(19) United States
(12) Patent Application Publication
(10) Pub. No.: US 2024/0012953 A1
(43) Pub. Date: Jan. 11, 2024

(54) AI ADVISOR FOR INCORPORATION OF HARDWARE CONSTRAINTS INTO DESIGN

(71) Applicant: Siemens Aktiengesellschaft, Munich (DE)

(72) Inventors: Andras Varro, Lawrenceville, NJ (US); Amit Pandey, Princeton, NJ (US)

(73) Assignee: Siemens Aktiengesellschaft, Munich (DE)

(21) Appl. No.: 17/999,958

(22) PCT Filed: May 29, 2020
(86) PCT No.: PCT/US2020/035227

§ 371 Date: Nov. 28, 2022

(51) Int. Cl. G06F 30/10

(52) U.S. Cl. CPC G06F 30/10

(57) ABSTRACT

A system and method for computer aided design includes constructing, by an engineering software tool for a current project, a design of a circuit or a subsystem of an industrial system comprising a plurality of hardware elements. A project knowledge graph is constructed for the current project representing an ontology for a set of elements and element relationships, wherein the set of elements include the plurality of hardware elements. A feature extraction module extracts features of the project knowledge graph related to the plurality of hardware elements. An AI-based advisor runs integrated with the engineering tool during a current project and queries one or more reference knowledge graphs for common features extracted by the feature extraction module, and responsive to identifying additional information related to hardware constraints, generates and displays recommendations to the user for the design.

### TECHNICAL FIELD

This application relates to computer aided design (CAD). More particularly, this application relates to enhancement of CAD with an artificial intelligence advisor for incorporating hardware constraints into a design.

### BACKGROUND

When designing industrial systems, engineers rely on various engineering tools in the CAD domain including various software packages and applications tailored for one or more disciplines or domains of an industry, such as electrical, mechanical, automation, etc. A notable shortcoming with using such CAD tools is a lack of information related to physical and hardware limitations of target devices to guide the user during the design process. This can lead to a design that produces unexpected behavior or operation of the target device upon its deployment if the designed region of operation actually exceeds physical limits of the device, which could damage or destroy the device, and perhaps surrounding components within a shared circuit in the electrical domain or system loop in the mechanical domain.

A primary resource for hardware limitations and constraints is manufacturer datasheets, but these are often in a convoluted format from the perspective of both manual extraction and computer vision techniques, which hinders the design process. Another potential flaw with relying exclusively on datasheets is that the provided specifications may be inadequate for revealing limitations arising from dynamic operation, such as transient conditions. Hence, datasheets are typically an incomplete and inadequate resource for the required information.

Another source for learning hardware constraints can be expert knowledge obtained through consultation with experts who are well versed in the target device. However, direct consultation is inefficient and the information is frequently lost over time for lack of consistent storage or modeling of such information, or due to its general mishandling. With expert consults generally occurring in silos with narrow scope and within a localized workgroup, comprehensive expert knowledge is often not widely available to a general audience of current users and to future users. Such inconsistent availability of expert knowledge is a significant shortcoming for safe and efficient design of industrial systems with respect to hardware constraints.

While artificial intelligence (AI) based tools are available to assist a software user, such as BAYOU for writing methods and Codota for code completion, none of the conventional solutions incorporate knowledge of hardware constraints, nor do they extend to graphical based environments.

### SUMMARY

A software solution is disclosed which incorporates an AI-based advisor function to inform a user of a CAD based engineering tool if certain hardware limitations have been violated or if device performance may vary from what is expected. The AI-based advisor may generate and display a recommendation for the design, such as a different target design element or an additional design element to ensure safe operation.

In an aspect, a system is provided for computer aided design, the system including a processor and a memory having stored thereon modules executed by the processor, such as an engineering software tool configured to construct, for a current project, a graphical design of an electrical circuit or a subsystem of an industrial system with a plurality of hardware elements. The engineering software tool also displays a rendering of the design. A knowledge graph generator module extracts data from the graphical design and constructs a project knowledge graph for the current project having nodes and edges representing an ontology for a set of hardware elements and element relationships from the extracted data. A feature extraction module extracts features of the project knowledge graph related to the plurality of hardware elements. An artificial intelligence (AI) module is integrated with the engineering software tool during a current project and queries one or more reference knowledge graphs for common features extracted by the feature extraction module. Reference knowledge graphs are stored in a repository of archived data of previous projects, including additional information related to hardware constraints associated with the extracted features. The AI module generates recommendations for the design on the display of the rendered design responsive to identifying the additional information related to hardware constraints. The AI module communicates with a server-based AI module comprising a machine learning-based network trained using training data to recognize hardware constraints from knowledge graph analysis.

### BRIEF DESCRIPTION OF THE DRAWINGS

Non-limiting and non-exhaustive embodiments of the present embodiments are described with reference to the following FIGURES, wherein like reference numerals refer to like elements throughout the drawings unless otherwise specified.

FIG. 1 is a block diagram for an example of an AI-based advisor system for incorporation of hardware constraints into an engineering design in accordance with embodiments of the disclosure.

FIG. 2 shows a flowchart for an example of an AI-based advisor process for incorporating hardware constraints into design in accordance with embodiments of the disclosure.

FIG. 3 shows an example of a method for implementing an AI-based advisor in a design project in accordance with embodiments of this disclosure.

FIG. 4 shows an example of knowledge graphs applied in accordance with embodiments of the disclosure.

FIG. 5 shows an example of a rendered AI-based advisor sequence integrated with an engineering tool according to embodiments of the disclosure.

FIG. 6 illustrates an example of a computing environment within which embodiments of the disclosure may be implemented.

### DETAILED DESCRIPTION

Methods and systems are disclosed for providing an AI assisted design tool that incorporates hardware constraints into the design elements. During a project, such as an engineering design project, a user of a software application (e.g., an engineering CAD based tool for rendering circuit or system designs in 2D or 3D) may add elements one by one to a circuit or system loop for an industrial system or subsystem, such as an automation system. To solve the aforementioned technical problem of risking damage to hardware deployed according to the project design, an AI-based advisor feature may run in the background, being integrated with the design software application during the design phase to provide recommendations to the user. For instance, the software application may display notifications from the AI-based advisor on the display screen concurrently with a graphical representation of design project rendered by an engineering tool in real time. As an example, a circuit element may be selected from a display of candidate elements and placed onto the circuit being designed, and in response the AI-based advisor may recognize that a similar design in previous projects included an additional protective element to prevent damage to the new element, such as a limiter element that controls operating voltage within a safe range of operation. The solution proposed in this disclosure includes an AI module trained to learn from reference knowledge graphs constructed from project archives, expert knowledge, internal standards, and/or industry standard rules and regulations.

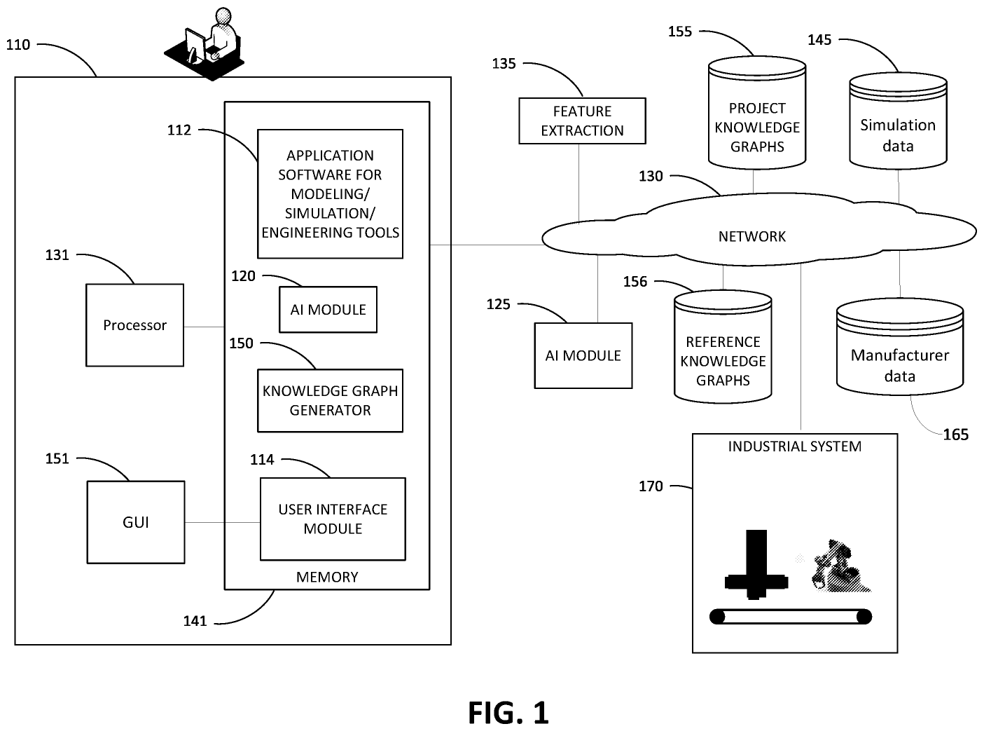

FIG. 1 is a block diagram for an example of an AI-based advisor system for incorporation of hardware constraints into an engineering design in accordance with embodiments of the disclosure. A computing device 110 includes a processor 131, memory 141, and graphical user interface (GUI) 151 on which a user (e.g., an engineer) works on a project related to an industrial automation system 170. In an embodiment, application software 112 is deployed on the computing device 110, stored on memory 141 and executed by processor 131, for various design tasks in a project. Application software 112 may include one or more programs dedicated to modeling, simulation, or other engineering tools. A knowledge graph generator 150 extracts features of a current design project executed by application software 112 to generate an ontology of the design, including interconnected hardware elements. User interface module 114 provides an interface from the application software 112 to the GUI 151 allowing the user to interface with the application software 112 and view renderings of design elements on a display. The application software 112 may perform simulations of a project design and to be stored externally as simulation data 145 as shown, stored locally in memory 141, or a combination of both.

Industrial system 170 may be partially or fully deployed during the design project being constructed and tested by the application software 112. For example, the design project may involve a multidisciplinary design with engineers of various disciplines each performing computer aided design using engineering software tools configured for respective disciplines. An automation engineer may contribute automation system design aspects of the industrial system 170, which may include a conveyor, a milling machine and a robot in different stages of deployment, including auxiliary and control systems, such as sensors and electrical driver circuits. Similarly, electrical subsystems of industrial system 170 may be designed by an electrical engineer using electrical engineering software tools to construct designs of electrical circuits and related control systems. A mechanical engineer may design mechanical subsystems of industrial system 170 using mechanical engineering software tools. For each of the various engineering disciplines, hardware constraints of industrial system 170 can be incorporated into the design project according to the embodiments of this disclosure.

In an embodiment, an engineering software tool of application software 112 is configured to execute a project design for industrial system 170, including constructing a graphical design of a subsystem, such as an electrical circuit, where the graphical design includes hardware elements, and the design is rendered for display to a user.

In an embodiment, a knowledge graph generator 150 is configured to extract data from the graphical design and construct a project knowledge graph for the current project comprising nodes and edges representing an ontology for a set of elements and element relationships from the extracted data. The set of elements includes the plurality of hardware elements. For example, one or more design projects may concurrently run using application software 112, and a project knowledge graph may be generated for each project, and stored in a project knowledge graph repository 155. One or more project knowledge graphs 155 are accessible to the computing device 110, simulation data 145, and industrial system 170 through network 130. A knowledge graph is an ontology representing the elements of the industrial system design as nodes with edges representing relationships between the nodes. The ontology evolves over time with updates to capture changes to the design as provided by a project export function of application software 112 in real time.

Hardware constraint information may be stored in an ontology of data in reference knowledge graphs 156, including archived data of previous projects. For example, information found in internal standards, and/or industry standard rules and regulations, may be compiled and added to historical data, such as circuit and system loop designs from previous projects, which may include simulation data 145 with results of simulations performed in previous projects by simulation application software 112. Reference knowledge graphs 156 may be further enhanced by engineering feedback, notes and expert knowledge accumulated during previous projects, as well as manufacturer data 165.

Computing device 110 may be operated by a user to begin a project by calling up previous projects similar to the current project, such as designing a particular portion of the industrial automation system 170. For example, using an application software 112 such as a TIA portal engineering tool, the GUI 151 may display a menu from which the user may select various component types, such as a robot sensor that is to be connected to a robot. As the elements of the current project are selected and arranged using the engineering software tools of application software 112, the elements are mapped to one or more of the project knowledge graphs 155. In an aspect, several projects may be running concurrently in parallel, each having a respective project knowledge graph 155 that can be updated by the addition, change, or removal of an element, whereby one or more nodes and edges may be added, removed, or rearranged by connected edges.

As shown in FIG. 1, AI module 125 is available to the computing device 110 via the network 130. For example, AI module 125 may be implemented as a server accessible to computing device 110 via network 130, which may be a private network or the internet. An AI-based advisor feature may be executed by the AI module 125 for assisting the user while one or more engineering software tools of application software 112 are concurrently running, providing recommendations to the user on user interface 151 with respect to hardware constraints. In an aspect, a local AI module 120 may be stored in memory 141 to work in tandem with AI module 125, allowing the AI-based advisor feature to be embedded in application software 112 (e.g., an application plugin to enable a client in computing device 110 to interface with a server based AI module 125), running in the background. In an embodiment, a recommendation with respect to hardware constraints for the new element may be displayed to the user a recommendation with respect to hardware constraints for a new element may be displayed to the user without having to leave the running engineering tool, in response to a new element being added to the design. To provide such assistance, AI module 125 learns from one or more sources of knowledge both during a learning phase, and then continues to learn during the project engineering phase. In an embodiment, AI module 125 includes a machine learning-based network configured to learn user choices associated with design elements, such as combination of elements relating to hardware constraints based on information extracted from manufacturer data 165 (e.g., manufacturer data sheet data stored in a database). In an embodiment, AI module 125 may learn hardware constraints from simulation data 145 accumulated during previous simulations performed in previous projects using application software 112 for simulation. In some embodiments, the AI module 125 may be implemented as a Bayesian network that learns from previous projects based on ontology of reference knowledge graphs 156 and then provides recommendations to the user during the project based on prediction of element combinations, element selections, and/or parameter settings of selected elements. Such a rule based system achieves an understanding from an ontology or other data representation that the current design project relates to hardware element that has one or more constraints for safe operation. In another embodiment, the AI module 125 compares reference knowledge graphs 156 to a new project knowledge graph 155 of the current project to detect discrepancies. Based on discrepancies, the AI module 125 may apply inference algorithms to generate a recommendation and may send a notification to the user as an assistance function indicating a potential risk for a design element with respect to exceeding manufacturer operational limits or other potential causes for alarm.

Feature extraction module 135 is configured to extract relevant features of the design from a development environment (e.g., Matlab, Simulink, NI Labview, or the like) during the project engineering phase. In an embodiment, as the project is being developed by the user using the application software 112, feature extraction module 135 reads the elements of the design and the AI module 125 queries the extracted elements against an existing reference knowledge graphs 156. In an embodiment, feature extraction module 135 may extract features of the project design from the project knowledge graph 155. For example, as a new element is added to the design by application software 112, the knowledge graph generator 150 may encode information of the element to the project knowledge graph stored in repository 155, from which the feature extraction module 135 extracts the new features. Feature extraction module 135 may be remotely deployed and accessible via network 130, or may be deployed in local memory 141.

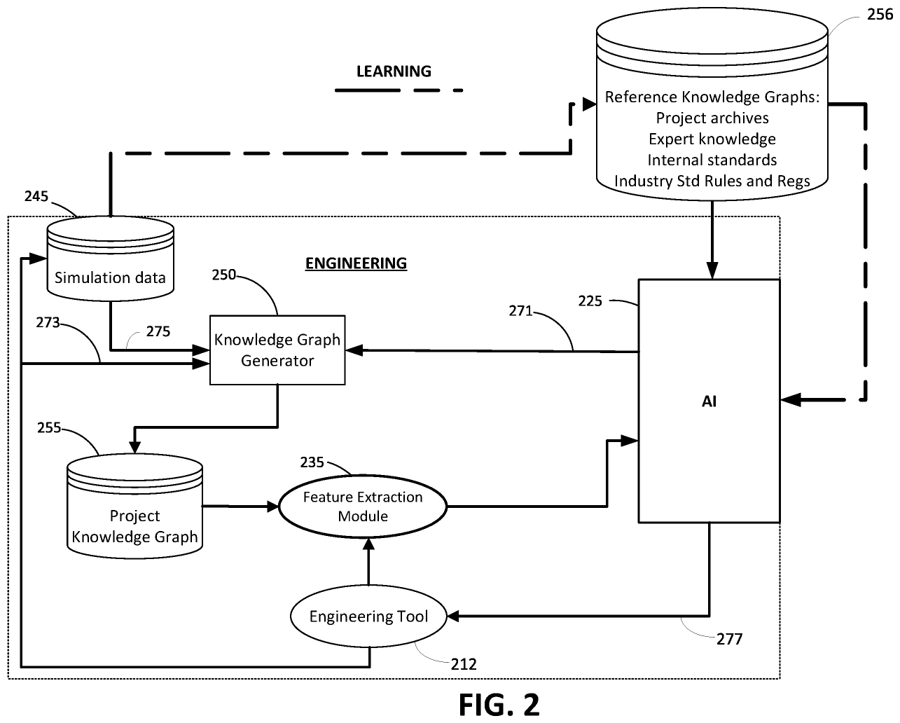

FIG. 2 shows a flowchart for an example of an AI-based advisor process for incorporating hardware constraints into design in accordance with embodiments of the disclosure. AI module 225 is shown as operating in learning phase and engineering phase. During a learning phase, AI module 225 is trained using training data to recognize hardware constraints from knowledge graph analysis. Training data may be applied using supervised or unsupervised training methods to a machine learning based network using previous engineering experience and expert knowledge from project archives, internal standards (e.g., standards and policies of a company as owner and operator of the industrial system facility being designed), industry standard rules and regulations. For example, these information sources may be stored as reference knowledge graphs 256. Examples of supervised learning include the following cases where certain features will be associated with the data. Hardware limitations may be extracted from engineer notes recorded in previous projects or manufacturer datasheets using natural language processing (NLP) based techniques and then stored in the reference knowledge graphs 256. For example, a manufacture datasheet contains a table of key information which is associated with easily interpretable labels, e.g. maximum rated voltage. In these situations, it is relatively easy for an automated NLP algorithm to extract this information. On the other hand, there may be instances where the NLP can extract the relevant information from a data sheet deemed to be too convoluted for manual extraction. However, in some instances an expert may provide relevant components of a datasheet, such as situations where automatic NLP of a datasheet cannot be performed. In an embodiment, supervised training relates to the mapping of a current project to a previous project, where two projects which use the hardware components could be categorized as similar, and the hardware components are used as features to determine similarity. With respect to unsupervised approaches, various document or code embedding techniques (e.g. code2vec) could be employed to determine the similarity of two projects, such as in terms of similar code.

In an embodiment, reference knowledge graphs 256 may include information obtained by feedback from an engineer, which can be from the project archives that stores previous usage of the engineering tool 212. For example, the feedback may be related to a user response to previous AI-based advisor recommendations, such as an engineer declining a recommendation, then recorded as ‘not useful’ by the AI-based advisor. In such a situation, the AI module 225 will learn that the recommendation does not make sense. Engineer feedback can also be applied as supervised training data for AI module 225 where the engineer inputs known patterns or solutions. Alternatively, the AI module 225 can detect the state of a previous project, for instance if the coding generated by an application software it is able to successfully build or compile. Based on this detected state, AI module 225 can provide suggestions automatically in an engineering phase during the project development when a similar state is encountered. Other examples of state of previous project include hardware configuration, compiler settings, simulation parameters or other meta data which could be used as information for AI module 225 to advise the user.

During the engineering phase, knowledge graph generator 250 constructs project knowledge graph 255 used by AI module 225 to provide feedback 277 on the parameter or software code being written by the engineer within an engineering tool 212. Feedback may take any one of several forms, including a recommendation for selecting a variation of the target element being currently added to the design, recommendation for an auxiliary element to protect the operating range of the target element, recommendation for interfacing between elements in a circuit or system loop, and/or a request for approval of the recommendation. Feedback 277 may appear in a portion of the display screen on which engineering tool 212 is running. In an embodiment, engineering tool 212 executes one or more application software programs to build the project knowledge graph 255. For example, engineering tool 212 may execute a simulation using a simulation software application, the results being stored as simulation data 245. In an embodiment, the advisory function of the AI module 225 includes more than just static rule based evaluation, such as reacting to simulation data 245 that may include dynamic transient levels of operation or environmental conditions (e.g., variable voltage, current, power, fluid flow, temperature, control signal, and the like). For example, AI module 225 may identify transient properties from reference knowledge graphs 256 when comparing extracted features from simulation data 245. The feature extraction module 235 may extract the relevant features of the design, either in response to an action by the engineering tool 212, or performed by periodic scans of the design. The extraction may be taken from the project knowledge graph 255 and/or the user's development environment implemented by the engineering tool 212 (e.g., Matlab, Simulink, or NI LabView). For example, features may include aspects such as a hardware board being used, or the different functional blocks being employed in the design (e.g., a proportional-integral-derivative (PID) controller block or a pulse width modulation (PWM) module). The relevant extracted features may also include transient properties revealed by simulation data 245. The extracted features may be sent to AI module 225, which then may query the features against the reference knowledge graphs 256 containing ontologies of data as described above for reference knowledge graphs 156. The project knowledge graph generator 250 encodes the information on hardware limitations 271 coming from the AI module 225 query and incorporates the information into project knowledge graph 255. Project knowledge graph generator 250 may also construct the project knowledge graph 255 using real time data inputs 273 from the graphical design performed by engineering tool 212, simulation data 275 resulting from simulations performed by engineering tool 212, or both. AI module 225 evaluates the current state of the project design against the query results, such as matching ontology patterns of the project knowledge graph 255 against patterns of the reference knowledge graphs 256. Based on the evaluation of the query, AI module 225 generates a recommendation and sends a notification in feedback signal 277 to the user within the integrated engineering tool 212 in the form of a statement and/or question. Alternatively, the recommendation may be in graphical form, such as overlaying a proposed element according to the recommendation, with the user presented the option of accepting or rejecting the recommended element. The user may accept or reject the recommendation, which may trigger the project export to record the decision into the knowledge graph 255.

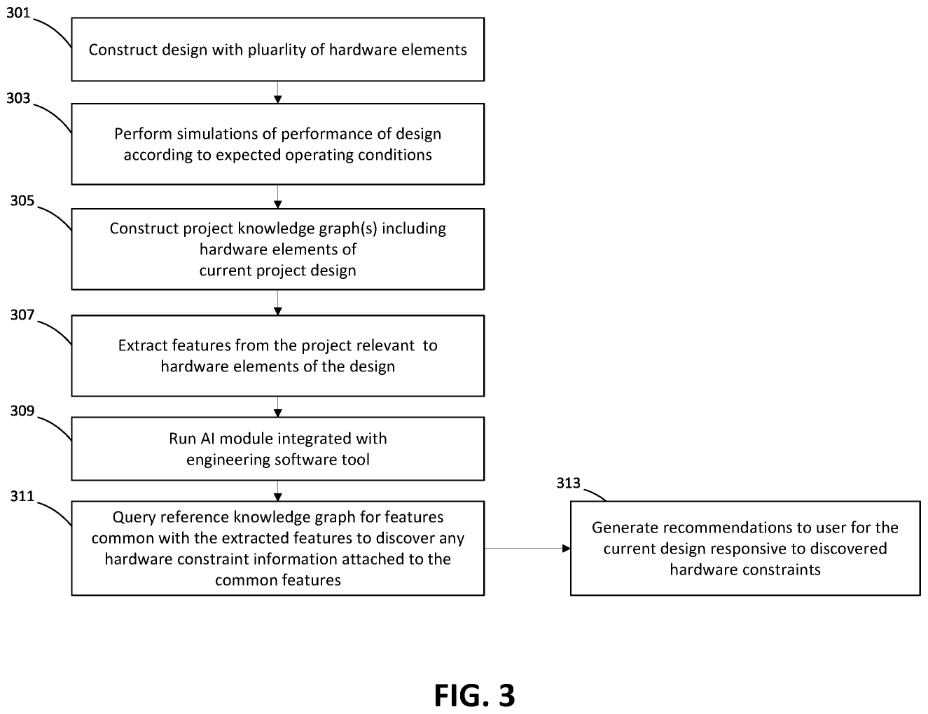

FIG. 3 shows an example of a method for implementing an AI-based advisor in a design project in accordance with embodiments of this disclosure. At 301, engineering tool 212 constructs a design with a plurality of hardware elements. An engineering tool 212 may perform a simulation of the project design at 303 according to expected operating conditions. One or more project knowledge graphs may be constructed at 305 with elements of the current project design, including hardware elements. As each element of the design is added using the engineering tool 212, knowledge graph generator adds one or more nodes to knowledge graph through project export according to the ontology of the related elements. In an embodiment, the project knowledge graph may include elements related to the simulation 303.

At 307, the feature extraction module 235 extracts features relevant to hardware elements of the design from application software running in the user development environment, such as engineering tool 212, and/or from the project knowledge graph 255. In instances where simulations are performed at 303, the feature extraction module 235 extracts features from the simulation which may correlate with simulations of previous projects reflected in the reference knowledge graphs. Transient states of design elements may be revealed by the simulation data which may be useful information related to hardware constraints and may be a feature learned from previous designs or other reference knowledge graph information. In an embodiment, simulation data of project archives may indicate unexpected results, which may be a dynamic trigger for the AI module to advise the user of candidate recommendations for protecting a target hardware element in the design. For example, a simulation for an electrical circuit design project may simulate various operating conditions for the circuit and may reveal an upper current limit being exceeded. AI module 225, having been trained to learn hardware constraints from various information sources as described above, may run in the background, integrated with engineering tools 212 during the project design at 309. The AI module 225 queries the reference knowledge graph 256 for features common with the extracted features at 311, for the purpose of discovering related characteristics attached to the common features, such as hardware constraint data, not present in the features of the current project according to the project knowledge graph 256. The AI module 255 may also analyze extracted simulation results that were unfavorable from reference knowledge graphs corresponding to simulation data extracted from project knowledge graph 255 and in response, trigger an advisory notification as a warning or a recommendation to the user regarding potential violation of hardware constraints. The AI module 225 generates and displays recommendations to the user responsive to the discovered hardware constraints at 313.

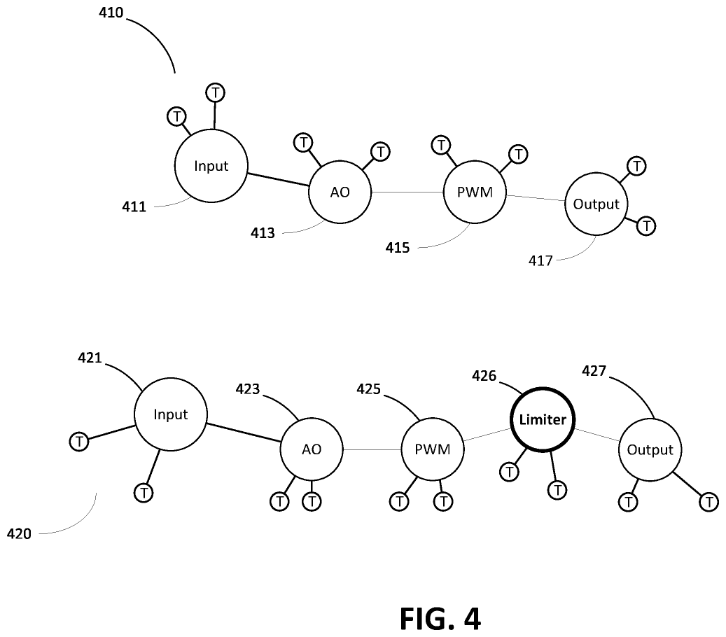

FIG. 4 shows an example of knowledge graphs applied according to embodiments of this disclosure. A first knowledge graph 410 is shown to represent a real time ontology of a current design of an ongoing project. For example, an electrical circuit having an input, an arithmetic operation, a pulse width modulation element and an output may be represented by object nodes 411, 413, 415, 417 in knowledge graph 410. Object nodes have tag nodes T representing various associated characteristics or properties for the respective node. For example, input node 411 may include a name tag and value tag. Arithmetic operation node 413 may have an operation tag indicating the type of arithmetic operation (e.g., sum) and a saturation tag representing a value limit. PWM node 415 represents a pulse width modulator element with tag nodes for switching frequency value and dead time value. As shown in FIG. 4, a second knowledge graph 420 represents one of many reference knowledge graphs stored as a repository of knowledge from prior projects. In an embodiment, such a referenced knowledge graph may be retrieved as a reference for the current project due to similar objects with similar configuration. In this instance, knowledge graph 420 resembles knowledge graph 410 with respect to object nodes and arrangement of interconnections except for the additional object of a duty cycle limiter node 413. Duty cycle limiter node 426 may have tags for maximum duty cycle value and minimum duty cycle value. In response to recognizing the duty cycle limiter object node 426 as an inconsistency with the first knowledge graph 410, AI module 225 may generate a textual or graphical notification to the user that this duty cycle limiter is recommended for the current circuit under design. In practice, first and second knowledge graphs 410, 420 may represent an ontology having hundreds of nodes to capture many various elements and associated tags related to a current project. Other projects may include other engineering disciplines or domains, such as for design projects with mechanical systems or automation systems, which can be similarly represented using knowledge graph ontology, and then be analyzed for hardware limitations according to the embodiments of this disclosure.

In an aspect, project knowledge graphs 155, 255 can be built on top of databases to link datasets in a meaningful way based on a context. To serve the applications of this disclosure, knowledge graphs allow queries of stored information to be performed efficiently. For example, the data may be encoded as triples of subject-object-predicate statements.

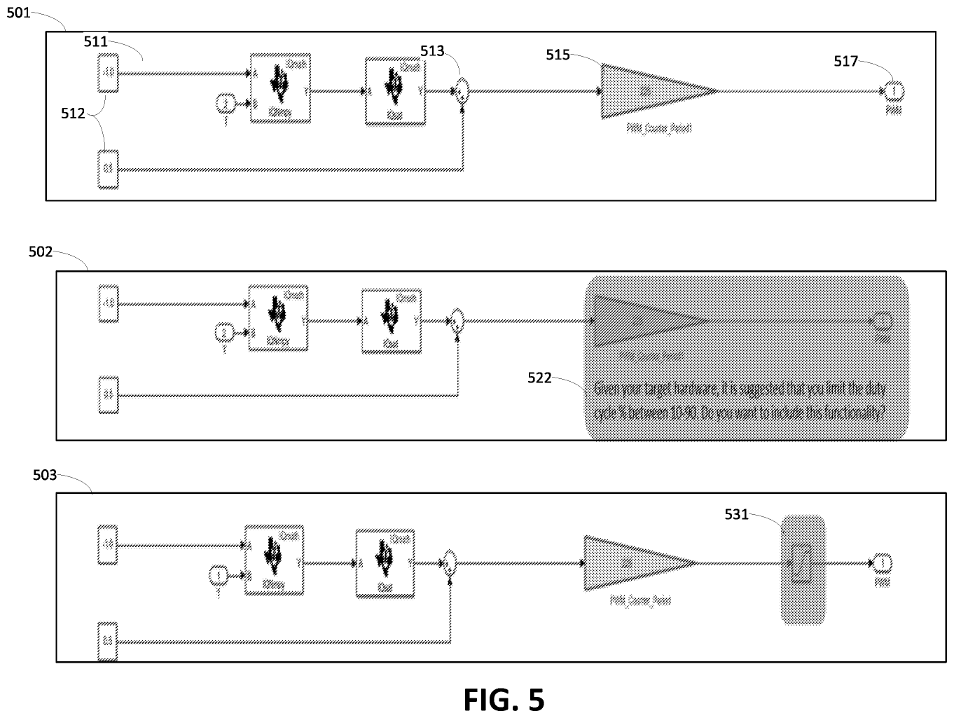

FIG. 5 shows an example of a rendered AI-based advisor sequence integrated with an engineering tool according to embodiments of the disclosure. As a specific example of a project design, FIG. 5 shows a time progression of a block diagram representing a desired functionality. For example, in slide 501, an engineering software tool is used to construct a circuit function block which is rendered on a graphical user interface shown as circuit 511 including inputs 512, arithmetic operator 513. In response to an action of adding a circuit element 515 to the circuit function block 511 to generate a PWM waveform at output pin 517, feature extraction module 135 reacts to the design change and extracts this new PWM feature from the development environment and sends to the AI module 125, which evaluates the pattern of connected elements surrounding the PWM and queries the reference knowledge graphs for any matching features. If any violation is detected from the query, (i.e., a discrepancy between current design and expected design according to successful designs of previous projects), the AI module 125 may generate a notification and may also propose a solution which can be displayed through the AI-based advisor feature implemented by AI module 120 running in the background with engineering software tool 112. As shown in slide 502, such a notification is displayed on the graphical representation of the circuit by the AI-based advisor feature as a text block overlay 522 on the new element 521. For example, the AI module 225 may identify hardware constraint information attached to the matching feature from the reference knowledge graph, and send a textual message such as “Given your target hardware, it is suggested to limit the duty cycle between 10%-90%. Do you want to include this functionality?” At slide 503, a limiter device element 531 is automatically added to the circuit by the engineering tool responsive to the user accepting the recommendation of the advisor function of the AI module 225. For example, the result of the AI module query may identify a common PWM feature in the reference knowledge base and recognize through pattern matching that in one or more previous projects (e.g., a majority of similar designs with PWM), the limiter device element 531 was included in the circuit for the purpose of limiting the operating range between 10-90%. Such an example is illustrated in FIG. 4 as described above for the discrepancy between knowledge graphs 410 and 420 revealing limiter 426. Based on this query, the AI module generates a notification to this effect and may also work in conjunction with the engineering tool 212 to automatically add the suggested element 531 to the design upon user approval. Accordingly, latent hardware constraints may be discovered and incorporated into the project design using the AI-based advisor.

Advantages of the disclosed embodiments include is the ability to incorporate prior experience, knowledge and known limitations regarding hardware design directly into software design packages. By automatically incorporating hardware constraint information into the design process, drastic reduction in development time and cost can be gained. In contrast, conventional software-based solutions for hardware design provide minimal feedback if a design will perform in the expected manner once it has been uploaded to the target device.

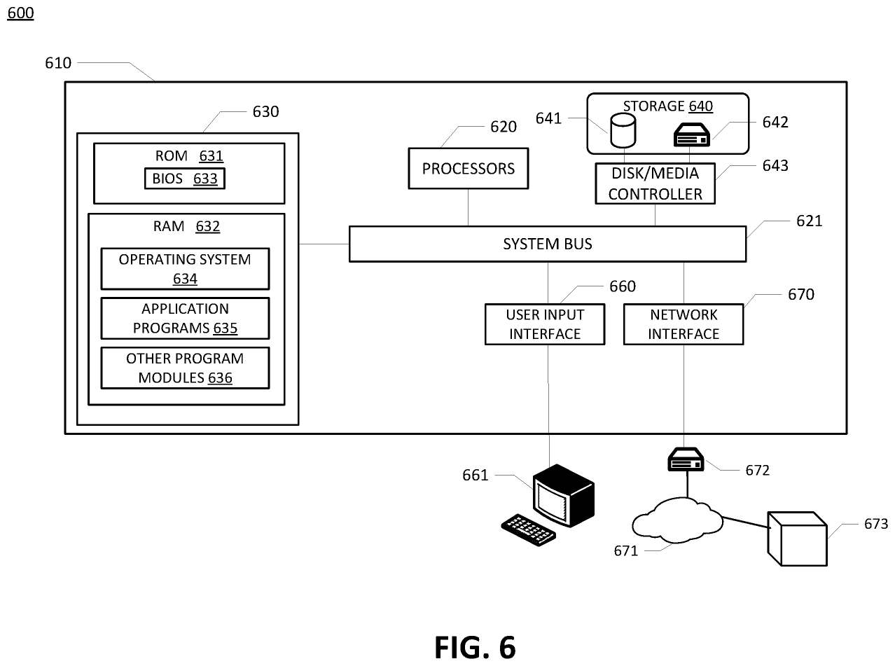

FIG. 6 illustrates an example of a computing environment within which embodiments of the present disclosure may be implemented. A computing environment 600 includes a computer system 610 that may include a communication mechanism such as a system bus 621 or other communication mechanism for communicating information within the computer system 610. The computer system 610 further includes one or more processors 620 coupled with the system bus 621 for processing the information. In an embodiment, computing environment 600 corresponds to system for an AI-based advisor to incorporate hardware constraints in a project design for ensuring safe operation, in which the computer system 610 relates to a computer described below in greater detail.

The processors 620 may include one or more central processing units (CPUs), graphical processing units (GPUs), or any other processor known in the art. More generally, a processor as described herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting or transmitting information for use by an executable procedure or an information device, and/or by routing the information to an output device. A processor may use or comprise the capabilities of a computer, controller or microprocessor, for example, and be conditioned using executable instructions to perform special purpose functions not performed by a general purpose computer. A processor may include any type of suitable processing unit including, but not limited to, a central processing unit, a microprocessor, a Reduced Instruction Set Computer (RISC) microprocessor, a Complex Instruction Set Computer (CISC) microprocessor, a microcontroller, an Application Specific Integrated Circuit (ASIC), a Field-Programmable Gate Array (FPGA), a System-on-a-Chip (SoC), a digital signal processor (DSP), and so forth. Further, the processor(s) 620 may have any suitable microarchitecture design that includes any number of constituent components such as, for example, registers, multiplexers, arithmetic logic units, cache controllers for controlling read/write operations to cache memory, branch predictors, or the like. The microarchitecture design of the processor may be capable of supporting any of a variety of instruction sets. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

The system bus 621 may include at least one of a system bus, a memory bus, an address bus, or a message bus, and may permit exchange of information (e.g., data (including computer-executable code), signaling, etc.) between various components of the computer system 610. The system bus 621 may include, without limitation, a memory bus or a memory controller, a peripheral bus, an accelerated graphics port, and so forth. The system bus 621 may be associated with any suitable bus architecture including, without limitation, an Industry Standard Architecture (ISA), a Micro Channel Architecture (MCA), an Enhanced ISA (EISA), a Video Electronics Standards Association (VESA) architecture, an Accelerated Graphics Port (AGP) architecture, a Peripheral Component Interconnects (PCI) architecture, a PCI-Express architecture, a Personal Computer Memory Card International Association (PCMCIA) architecture, a Universal Serial Bus (USB) architecture, and so forth.

Continuing with reference to FIG. 6, the computer system 610 may also include a system memory 630 coupled to the system bus 621 for storing information and instructions to be executed by processors 620. The system memory 630 may include computer readable storage media in the form of volatile and/or nonvolatile memory, such as read only memory (ROM) 631 and/or random access memory (RAM) 632. The RAM 632 may include other dynamic storage device(s) (e.g., dynamic RAM, static RAM, and synchronous DRAM). The ROM 631 may include other static storage device(s) (e.g., programmable ROM, erasable PROM, and electrically erasable PROM). In addition, the system memory 630 may be used for storing temporary variables or other intermediate information during the execution of instructions by the processors 620. A basic input/output system 633 (BIOS) containing the basic routines that help to transfer information between elements within computer system 610, such as during start-up, may be stored in the ROM 631. RAM 632 may contain data and/or program modules that are immediately accessible to and/or presently being operated on by the processors 620. System memory 630 may additionally include, for example, operating system 634, application modules 635, and other program modules 636. Application modules 635 may include aforementioned modules described for FIG. 1 or FIG. 2 and may also include a user portal for development of the application program, allowing input parameters to be entered and modified as necessary.

The operating system 634 may be loaded into the memory 630 and may provide an interface between other application software executing on the computer system 610 and hardware resources of the computer system 610. More specifically, the operating system 634 may include a set of computer-executable instructions for managing hardware resources of the computer system 610 and for providing common services to other application programs (e.g., managing memory allocation among various application programs). In certain example embodiments, the operating system 634 may control execution of one or more of the program modules depicted as being stored in the data storage 640. The operating system 634 may include any operating system now known or which may be developed in the future including, but not limited to, any server operating system, any mainframe operating system, or any other proprietary or non-proprietary operating system.

The computer system 610 may also include a disk/media controller 643 coupled to the system bus 621 to control one or more storage devices for storing information and instructions, such as a magnetic hard disk 641 and/or a removable media drive 642 (e.g., floppy disk drive, compact disc drive, tape drive, flash drive, and/or solid state drive). Storage devices 640 may be added to the computer system 610 using an appropriate device interface (e.g., a small computer system interface (SCSI), integrated device electronics (IDE), Universal Serial Bus (USB), or FireWire). Storage devices 641, 642 may be external to the computer system 610.

The computer system 610 may include a user input interface or graphical user interface (GUI) 661, which may comprise one or more input devices, such as a keyboard, touchscreen, tablet and/or a pointing device, for interacting with a computer user and providing information to the processors 620.

The computer system 610 may perform a portion or all of the processing steps of embodiments of the invention in response to the processors 620 executing one or more sequences of one or more instructions contained in a memory, such as the system memory 630. Such instructions may be read into the system memory 630 from another computer readable medium of storage 640, such as the magnetic hard disk 641 or the removable media drive 642. The magnetic hard disk 641 and/or removable media drive 642 may contain one or more data stores and data files used by embodiments of the present disclosure. The data store 640 may include, but are not limited to, databases (e.g., relational, object-oriented, etc.), file systems, flat files, distributed data stores in which data is stored on more than one node of a computer network, peer-to-peer network data stores, or the like. Data store contents and data files may be encrypted to improve security. The processors 620 may also be employed in a multi-processing arrangement to execute the one or more sequences of instructions contained in system memory 630. In alternative embodiments, hard-wired circuitry may be used in place of or in combination with software instructions. Thus, embodiments are not limited to any specific combination of hardware circuitry and software.

As stated above, the computer system 610 may include at least one computer readable medium or memory for holding instructions programmed according to embodiments of the invention and for containing data structures, tables, records, or other data described herein. The term “computer readable medium” as used herein refers to any medium that participates in providing instructions to the processors 620 for execution. A computer readable medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 641 or removable media drive 642. Non-limiting examples of volatile media include dynamic memory, such as system memory 630. Non-limiting examples of transmission media include coaxial cables, copper wire, and fiber optics, including the wires that make up the system bus 621. Transmission media may also take the form of acoustic or light waves, such as those generated during radio wave and infrared data communications.

Computer readable medium instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, may be implemented by computer readable medium instructions.

The computing environment 600 may further include the computer system 610 operating in a networked environment using logical connections to one or more remote computers, such as remote computing device 673. The network interface 670 may enable communication, for example, with other remote devices 673 or systems and/or the storage devices 641, 642 via the network 671. Remote computing device 673 may be a personal computer (laptop or desktop), a mobile device, a server, a router, a network PC, a peer device or other common network node, and typically includes many or all of the elements described above relative to computer system 610. When used in a networking environment, computer system 610 may include modem 672 for establishing communications over a network 671, such as the Internet. Modem 672 may be connected to system bus 621 via user network interface 670, or via another appropriate mechanism.

Network 671 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 610 and other computers (e.g., remote computing device 673). The network 671 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 671.

It should be appreciated that the program modules, applications, computer-executable instructions, code, or the like depicted in FIG. 6 as being stored in the system memory 630 are merely illustrative and not exhaustive and that processing described as being supported by any particular module may alternatively be distributed across multiple modules or performed by a different module. In addition, various program module(s), script(s), plug-in(s), Application Programming Interface(s) (API(s)), or any other suitable computer-executable code hosted locally on the computer system 610, the remote device 673, and/or hosted on other computing device(s) accessible via one or more of the network(s) 671, may be provided to support functionality provided by the program modules, applications, or computer-executable code depicted in FIG. 6 and/or additional or alternate functionality. Further, functionality may be modularized differently such that processing described as being supported collectively by the collection of program modules depicted in FIG. 6 may be performed by a fewer or greater number of modules, or functionality described as being supported by any particular module may be supported, at least in part, by another module. In addition, program modules that support the functionality described herein may form part of one or more applications executable across any number of systems or devices in accordance with any suitable computing model such as, for example, a client-server model, a peer-to-peer model, and so forth. In addition, any of the functionality described as being supported by any of the program modules depicted in FIG. 6 may be implemented, at least partially, in hardware and/or firmware across any number of devices.

It should further be appreciated that the computer system 610 may include alternate and/or additional hardware, software, or firmware components beyond those described or depicted without departing from the scope of the disclosure. More particularly, it should be appreciated that software, firmware, or hardware components depicted as forming part of the computer system 610 are merely illustrative and that some components may not be present or additional components may be provided in various embodiments. While various illustrative program modules have been depicted and described as software modules stored in system memory 630, it should be appreciated that functionality described as being supported by the program modules may be enabled by any combination of hardware, software, and/or firmware. It should further be appreciated that each of the above-mentioned modules may, in various embodiments, represent a logical partitioning of supported functionality. This logical partitioning is depicted for ease of explanation of the functionality and may not be representative of the structure of software, hardware, and/or firmware for implementing the functionality. Accordingly, it should be appreciated that functionality described as being provided by a particular module may, in various embodiments, be provided at least in part by one or more other modules. Further, one or more depicted modules may not be present in certain embodiments, while in other embodiments, additional modules not depicted may be present and may support at least a portion of the described functionality and/or additional functionality. Moreover, while certain modules may be depicted and described as sub-modules of another module, in certain embodiments, such modules may be provided as independent modules or as sub-modules of other modules.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like can be additionally based on one or more other operations, elements, components, data, or the like. Accordingly, the phrase “based on,” or variants thereof, should be interpreted as “based at least in part on.”

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

What is claimed is:

1. A system for computer aided design, comprising:
a processor; and
a memory having stored thereon modules executed by the processor, the modules comprising:
an engineering software tool configured to construct, for a current project, a graphical design of an electrical circuit or a subsystem of an industrial system, the graphical design comprising a plurality of hardware elements, the engineering software tool further configured to display a rendering of the design;
a knowledge graph generator configured to extract data from the graphical design and construct a project knowledge graph for the current project comprising nodes and edges representing an ontology for a set of elements and element relationships from the extracted data, wherein the set of elements includes the plurality of hardware elements;
a feature extraction module configured to extract features of the project knowledge graph related to the plurality of hardware elements;
an artificial intelligence (AI) module integrated with the engineering software tool during a current project and configured to:
query one or more reference knowledge graphs for common features extracted by the feature extraction module, wherein the reference knowledge graphs are stored in a repository of archived data of previous projects, including additional information related to hardware constraints associated with the extracted features; and
generate and display recommendations for the design on the display of the rendered design responsive to identifying the additional information related to hardware constraints;
wherein the AI module communicates with a server-based AI module comprising a machine learning-based network trained using training data to recognize hardware constraints from knowledge graph analysis.

2. The system of claim 1, wherein the one or more reference knowledge graphs further includes at least one of expert knowledge, internal standards, or industry standard rules and regulations.

3. The system of claim 1, further comprising:
performing, by the engineering software tool, simulations of the electrical circuit or the subsystem under expected operating conditions;
wherein the project knowledge graph includes characteristics of the hardware elements based on the simulations.

4. The system of claim 3, further comprising:
extracting, by the feature extraction module, transient properties related to operating conditions or environmental conditions generated by the simulation;
wherein the recommendations are further based on the transient properties.

5. The system of claim 1, wherein the AI module training data includes engineer notes recorded from previous projects extracted by natural language processing.

6. The system of claim 1, wherein the AI module training data includes hardware constraint data from manufacturer data sheets extracted by natural language processing.

7. The system of claim 1, wherein the AI module training data includes engineering feedback extracted from project archives related to user response to AI recommendations.

8. The system of claim 1, wherein the AI module training data includes a detected state of coding generated by the engineering software tool being able to successfully build or compile.

9. A method for computer aided design, comprising:
constructing, by an engineering software tool, a graphical design of a circuit or a subsystem of an industrial system for a current project, the graphical design comprising a plurality of hardware elements;
constructing a project knowledge graph for the current project based on extracted data from the graphical design, the project knowledge graph comprising nodes and edges representing an ontology for a set of elements and element relationships respectively, wherein the set of elements includes the plurality of hardware elements;
extracting, by a feature extraction module, features of the project knowledge graph related to the plurality of hardware elements;
running an artificial intelligence (AI) module integrated with the engineering tool during a current project, comprising:
querying one or more reference knowledge graphs for common features extracted by the feature extraction module, wherein the reference knowledge graphs are stored in a repository of archived data of previous projects, including archived data of previous projects, including additional information related to hardware constraints associated with the extracted features; and
generating and displaying recommendations for the design on a display of a rendering of the graphical design responsive to identifying the additional information related to hardware constraints;
wherein the AI module communicates with a server-based AI module comprising a machine learning-based network trained using training data to recognize hardware constraints from knowledge graph analysis.

10. The method of claim 9, further comprising:
performing, by the engineering tool, simulations of the circuit or subsystem under expected operating conditions;
wherein the project knowledge graph includes characteristics of the hardware elements based on the simulations.

11. The method of claim 10, further comprising:
extracting, by the feature extraction module, transient properties related to operating conditions or environmental conditions generated by the simulation;
wherein the recommendations are further based on the transient properties.

12. The method of claim 9, wherein the AI module training data includes engineer notes recorded from previous projects extracted by natural language processing.

13. The method of claim 9, wherein the AI module training data includes hardware constraint data from manufacturer data sheets extracted by natural language processing.

14. The method of claim 9, wherein the AI module training data includes engineering feedback extracted from project archives related to user response to AI recommendations.

15. The method of claim 9, wherein the AI module training data includes a detected state of coding generated by the engineering software tool being able to successfully build or compile.
